(19) United States
(12) Patent Application Publication
(10) Pub. No.: US 2025/0007246 A1
(43) Pub. Date: Jan. 2, 2025

(54) METHOD FOR PRODUCING A PLURALITY OF SURFACE-EMITTING SEMICONDUCTOR LASER DIODES

(71) Applicant: ams-OSRAM International GmbH, Regensburg (DE)

(72) Inventors: Laura KREINER, Regensburg (DE); Hubert HALBRITTER, Dietfurt (DE)

(73) Assignee: ams-OSRAM International GmbH, Regensburg (DE)

(21) Appl. No.: 18/579,587

(22) PCT Filed: Jun. 14, 2022
(86) PCT No.: PCT/EP2022/066167

§ 371 Date: Jan. 16, 2024

(30) Foreign Application Priority Data
Jul. 16, 2021 (DE) 102021118463.0

(51) Int. Cl. H01S 5/183; H01S 5/30

(52) U.S. Cl. CPC H01S 5/18394; H01S 5/3013

(57) ABSTRACT

The invention relates to a method for producing a plurality of surface-emitting semiconductor laser diodes, including the following steps:—providing a growth substrate,—applying a mask layer with a plurality of openings onto the growth substrate, so that regions of the growth substrate are exposed through the openings,—applying a first intermediate layer at least onto the exposed regions of the growth substrate, the first intermediate layer having a quasi two-dimensional material, and—epitaxial growing of an epitaxial semiconductor layer sequence on the first intermediate layer, wherein the epitaxial semiconductor layer sequence has an active layer for generating electromagnetic radiation.

### CROSS-REFERENCE TO RELATED APPLICATIONS

The present application is a national stage entry from International Application No. PCT/EP2022/066167, filed on Jun. 14, 2022, published as International Publication No. WO 2022/285059 A1 on Jan. 19, 2023, and claims priority to German Patent Application No. 10 2021 118 463.0, filed Jul. 16, 2021, the disclosures of all of which are hereby incorporated by reference in their entireties.

### FIELD

A method for producing a plurality of surface-emitting semiconductor laser diodes is specified herein.

### BACKGROUND

The paper Karrakchou et al., Scientific Reports 10, 21709 (2020), describes a method for producing a light-emitting diode.

An improved method for producing a plurality of surface-emitting semiconductor laser diodes in a wafer compound is to be specified, which is configured to ensure a high quality of the epitaxial semiconductor material. In particular, it should be possible to easily detach the semiconductor chips from the growth substrate. This object is solved by a method comprising the steps of claim 1.

Advantageous embodiments and further developments of the method are specified in the dependent claims.

### SUMMARY

According to an embodiment of the method for producing a plurality of surface-emitting semiconductor laser diodes, a growth substrate is provided. The growth substrate can comprise, for example, sapphire, silicon carbide, or gallium nitride, or can be made of one of these materials.

In particular, the growth substrate can be a wafer, for example with a diameter of at least 6 inches. The process of producing a plurality of surface-emitting semiconductor laser diodes on large diameter wafers is usually less expensive than on small diameter wafers.

According to a further embodiment of the method, a mask layer having a plurality of openings is applied onto the growth substrate, such that regions of the growth substrate are exposed through the openings. Preferably, the mask layer is arranged in direct contact with the growth substrate. For example, the mask layer can be deposited by chemical vapor deposition.

The mask layer preferably comprises a dielectric material or is formed from a dielectric material. For example, an oxide, such as silicon dioxide, or a nitride is suitable as a dielectric material for the mask layer.

The features described here and below for one opening can apply to all openings. However, the features may also differ for different openings. An opening has, for example, a circular, oval, square or rectangular shape in plan view. Furthermore, openings with an arbitrary curved and/or polygonal shape are possible. The openings can be created using photolithographic techniques and etching, for example.

According to a further embodiment of the method, a first intermediate layer is applied at least onto the exposed regions of the growth substrate, wherein the first intermediate layer comprises or consists of a quasi-two-dimensional material. Here and in the following, quasi-two-dimensional materials are crystalline materials having layers of atoms or molecules. These layers of atoms or molecules are weakly bonded together, for example, via van der Waals forces. In particular, these layers of atoms or molecules can be easily detached from each other, in particular mechanically.

The first intermediate layer can be applied, for example, by gas phase epitaxy, in particular metal-organic gas phase epitaxy, at least to the exposed regions of the growth substrate.

The first intermediate layer can also be deposited over the exposed regions of the growth substrate and over the mask layer. Homogeneous regions of the first intermediate layer can form on the exposed regions of the growth substrate. By contrast, the first intermediate layer can have inhomogeneous regions with an inhomogeneous structure on the mask layer.

According to a further embodiment of the method, an epitaxial semiconductor layer sequence is epitaxially grown on the first intermediate layer, wherein the epitaxial semiconductor layer sequence comprises an active layer for generating electromagnetic radiation. For example, the epitaxial semiconductor layer sequence comprises a layer of an n-doped semiconductor material and a layer of a p-doped semiconductor material, between which the active layer is disposed. The active layer can include at least one quantum well layer. In addition, the active layer can have at least one barrier layer. During operation, the active layer can emit light, for example, in particular in a spectral range between and including infrared light and ultraviolet light.

For example, the epitaxial semiconductor layer sequence is epitaxially grown on the first intermediate layer by gas phase epitaxy, in particular metal-organic gas phase epitaxy. In particular, the epitaxial semiconductor layer sequence can be heteroepitaxially grown on homogeneous regions of the first intermediate layer. In this case, the homogeneous regions of the first intermediate layer are arranged on the exposed regions of the growth substrate.

The bond between the first intermediate layer and the epitaxial semiconductor layer sequence epitaxially grown thereon can be weak. For example, the first intermediate layer and the epitaxial semiconductor layer sequence are weakly bonded to each other by Van der Waals forces. In particular, the epitaxial semiconductor layer sequence can slide on the first intermediate layer without stress. Thus, advantageously, it is generally not necessary to adjust the lattice parameters of the first intermediate layer and the epitaxial semiconductor layer sequence. In particular, this makes it possible to produce InGaN-based semiconductor laser diodes with high indium doping and thus emission at longer wavelengths, for example in the red spectral range.

Semiconductor material deposited on inhomogeneous regions of the first intermediate layer above the mask layer can form an amorphous structure of semiconductor material. The epitaxial growth of the epitaxial semiconductor layer sequence thus occurs, in particular, selectively on homogeneous regions of the first intermediate layer that are located on exposed regions of the growth substrate. This allows epitaxial semiconductor layer stacks to form in the openings of the mask layer. These semiconductor layer stacks can be epitaxially grown in the wafer compound. Amorphous semiconductor material that formsin edge regions of a semiconductor layer stack, for example, can be removed in later process steps.

For example, the size of the openings is matched to the size of semiconductor chips of the surface-emitting semiconductor laser diodes. Furthermore, the semiconductor layer stacks can be easily detached from the growth substrate by mechanically detaching the layers of atoms or molecules within or at the edge of the intermediate layer. In particular, this can prevent breakage of the semiconductor layer stacks during mechanical detachment from the growth substrate. Furthermore, formation of defects in the semiconductor layer stacks can be reduced by the easy mechanical detachment. Thus, epitaxial growth of a plurality of surface-emitting semiconductor laser diodes having, for example, a nitride compound semiconductor material can be performed with high quality in a wafer compound on a low-cost sapphire wafer. Alternatively, a GaN wafer can be used as a substrate, which has a comparable thermal expansion coefficient to the epitaxial semiconductor material. As a result, no additional thermal strains are introduced into the epitaxial semiconductor layer sequence during cooling after the growth process. The subsequent mechanical detachment of the growth substrate allows it to be reused. Thus, a cost-effective producing process is possible even at a high substrate price. Furthermore, the growth and chip process can be carried out on wafers with at least 6 inches in diameter.

According to a preferred embodiment, the method for producing a plurality of surface-emitting semiconductor laser diodes comprises the following steps:
providing a growth substrate,
applying a mask layer having a plurality of openings onto the growth substrate, such that regions of the growth substrate are exposed through the openings,
applying a first intermediate layer at least onto the exposed regions of the growth substrate, wherein the first intermediate layer comprises a quasi-two-dimensional material,
epitaxially growing an epitaxial semiconductor layer sequence on the first intermediate layer, wherein the epitaxial semiconductor layer sequence comprises an active layer for generating electromagnetic radiation.

Preferably, these steps are performed in the order indicated above.

According to a further embodiment of the method, an area of the opening corresponds to the area of an aperture of the semiconductor laser diode.

For example, a diameter of an opening is approximately 10 micrometers.

According to a further embodiment of the method, at least one opening has an area greater than an aperture of the semiconductor laser diode. For example, an opening has a diameter between 10 micrometers and 40 micrometers, inclusive. For example, the distance between the edges of adjacent openings may be between 10 micrometers and 100 micrometers, inclusive. In this embodiment of the method, the area of the aperture of the semiconductor laser diode is defined in a later step of the method, for example, by depositing an electrically insulating layer on the epitaxial semiconductor layer sequence. Semiconductor material arranged laterally outside the aperture of the semiconductor laser diode remains inactive during operation and does not contribute to the generation of electromagnetic radiation.

Here and in the following, “lateral” is a direction extending parallel to a main extension plane of the epitaxial semiconductor layer sequence. In particular, lateral directions are orthogonal to the growth direction of the epitaxial semiconductor layer sequence. The material arranged laterally outside the aperture may be configured for heat dissipation. In this embodiment of the method, the shape of sidewalls of the epitaxial semiconductor layer sequence need not be controlled during epitaxial growth.

According to a further embodiment of the method, the mask layer comprises a dielectric. For example, the mask layer comprises an oxide, in particular silicon dioxide, or a nitride.

According to a further embodiment of the method, the quasi-two-dimensional material is selected from the group consisting of hexagonal boron nitride (h-BN), graphene, molybdenum disulfide, tungsten diselenide, fluorographene.

According to a further embodiment of the method, the first intermediate layer has a thickness between 0.5 nanometers and 100 nanometers, inclusive. In particular, the first intermediate layer has one or more layers of the two-dimensional atomic or molecular layers. Preferably, the first intermediate layer has a thickness of about 3 nanometers.

According to a further embodiment of the method, semiconductor layer stacks are epitaxially grown in the openings during epitaxial growth of the epitaxial semiconductor layer sequence. Hereby, the mask layer and/or an inhomogeneous region of the intermediate layer, which can be arranged on the mask layer, generally remain free of the epitaxial semiconductor layer sequence. A homogeneous first intermediate layer preferably forms on the exposed regions of the growth substrate. By contrast, the first intermediate layer can form inhomogeneously on the mask layer. This inhomogeneity may lead to an amorphous growth of the semiconductor material on inhomogeneous regions of the first intermediate layer, which can be located on the mask layer. Accordingly, the epitaxial semiconductor layer sequence can only grow epitaxially in the regions of the openings. Thus, a semiconductor layer stack can be epitaxially grown in each opening.

According to a further embodiment of the method, the semiconductor layer stacks have vertical side surfaces. By suitably adjusting the epitaxial growth conditions, for example the growth temperature and/or the growth rates, the semiconductor layer stacks can have vertical side surfaces. Thereby, a semiconductor layer stack with vertical side surfaces can be grown in each opening.

According to a further embodiment of the method, the epitaxial semiconductor layer sequence comprises a nitride compound semiconductor material. Nitride compound semiconductor materials are compound semiconductor materials containing nitrogen, such as the materials from the system InₓAl_{y}Ga_{1-x-y}N with 0≤x≤1, 0≤y≤1 and x+y≤1. This material does not necessarily have to have a mathematically exact composition according to the above formula. Rather, it can comprise, for example, one or more dopants as well as additional constituents. For the sake of simplicity, however, the above formula contains only the essential constituents of the crystal lattice (Al, Ga, In, N), even if these may be partially replaced and/or supplemented by small amounts of other substances.

Due to the heteroepitaxial growth of the epitaxial semiconductor layer sequence on the first intermediate layer, the indium content and/or the aluminum content of the nitride compound semiconductor material can be large, for example. In particular, the indium content and/or the aluminum content in the nitride compound semiconductor material can be so large that a direct epitaxial growth on a gallium nitride wafer can cause strains. Strains can cause crystal defects and reduce the crystal quality of the epitaxial semiconductor layer sequence.

An appropriate selection of the indium content and/or the aluminum content in the nitride compound semiconductor material enables a broad tunability of the wavelength of electromagnetic radiation generated in the active layer. For example, a surface-emitting semiconductor laser diode can emit electromagnetic radiation in a narrow wavelength range between and including red light and ultraviolet light during operation.

According to a further embodiment of the method, the epitaxial semiconductor layer sequence comprises at least a second intermediate layer which is arranged between a main surface of the epitaxial semiconductor layer sequence facing the first intermediate layer and the active layer, wherein the second intermediate layer comprises a quasi-two-dimensional material. For example, the second intermediate layer can be disposed between the first intermediate layer and the active layer. Preferably, the second intermediate layer may comprise the same quasi-two-dimensional material as the first intermediate layer. It is also possible for the second intermediate layer to comprise a different quasi-two-dimensional material than the first intermediate layer.

According to a further embodiment of the method, between the first intermediate layer and the second intermediate layer a semiconductor layer is arranged that is free of a quasi-two-dimensional material. The second intermediate layer is preferably not arranged directly on the first intermediate layer. For example, a semiconductor layer free of a quasi-two-dimensional material is first epitaxially grown on the first intermediate layer. In particular, the second intermediate layer is grown on this semiconductor layer subsequently. Thus, the semiconductor layer is arranged between the first intermediate layer and the second intermediate layer.

In order to increase the crystal quality of the epitaxial semiconductor layer sequence in the area of the active layer, it can be advantageous to grow at least a second intermediate layer as part of the epitaxial semiconductor layer sequence within the epitaxial semiconductor layer sequence. Multiple additional intermediate layers can also be grown within the epitaxial semiconductor layer sequence. The at least one second intermediate layer is disposed between the first intermediate layer and the active layer. Preferably, the second intermediate layer can be arranged at a position of the epitaxial semiconductor layer sequence that is higher than the highest point of the mask layer. Here and in the following, a height indication refers to the growth direction of the epitaxial semiconductor layer sequence. Disturbances of the epitaxial growth process at the edges of the openings of the mask layer, for example due to residues of crystallization nuclei, can reduce the quality of the epitaxial semiconductor layer sequence at an early stage of the epitaxial growth. In particular, the semiconductor layer sequence can be grown slowly in the beginning if a high crystal quality is desired. A second intermediate layer can prevent crystal defects from propagating to higher regions of the epitaxial semiconductor layer sequence, especially to the region of the active layer. Thus, the epitaxial semiconductor layer sequence between the first and a second intermediate layer can have a lower crystal quality, while the epitaxial semiconductor layer sequence in the region of the active layer can have a higher crystal quality. As a result, the growth process of the epitaxial semiconductor layer sequence can be accelerated and thus be more cost-effective.

According to a further embodiment of the method, the epitaxial semiconductor layer sequence comprises an etch stop layer, wherein the etch stop layer is arranged between the active layer and the intermediate layer closest to the active layer. The etch stop layer allows a precise stopping of an etching process or a mechanical removal process of the epitaxial semiconductor layer sequence. For example, the etch stop layer comprises a nitride or an oxide or consists of one of these materials. In particular, aluminum nitride or silicon nitride is suitable as a material for the etch stop layer.

The etch stop layer allows the final thickness of the epitaxial semiconductor layer sequence to be set with high precision. Thus, the length of an optical cavity of the surface-emitting semiconductor laser diode can be precisely adjusted. In particular, accurate adjustment of the length of the optical cavity is important for precisely setting the wavelength of the electromagnetic radiation emitted from the surface-emitting semiconductor laser diode during operation.

According to a further embodiment of the method, the epitaxial semiconductor layer sequence is mechanically detached from at least one intermediate layer and transferred to a carrier. The mechanical detachment and the transfer to the carrier can be carried out by means of a pick-and-place process. The carrier can have an electrical contact layer which serves to contact the epitaxial semiconductor layer sequence. Furthermore, the carrier can comprise a mirror, a reflective layer or a reflective layer sequence, such as a dielectric Bragg reflector. These are configured to reflect electromagnetic radiation generated by the active layer during operation. In particular, these form part of the optical cavity within which the epitaxial semiconductor layer sequence can be arranged.

According to a further embodiment of the method, the epitaxial semiconductor layer sequence is removed up to the etch stop layer. The removal can be performed, for example, by a wet or dry chemical etching process. Alternatively, the removal can be performed by a mechanical removal process. A suitable mechanical removal process is, for example, grinding or polishing of the epitaxial semiconductor layer sequence.

According to a further embodiment of the method, a contact layer of a light-transmitting material is deposited on a main surface of the epitaxial semiconductor layer sequence facing away from the carrier. The contact layer comprises, for example, a transparent conductive oxide or consists of a transparent conductive oxide (TCO).

Transparent conductive oxides are usually metal oxides, such as zinc oxide, tin oxide, cadmium oxide, titanium oxide, indium oxide or indium tin oxide (ITO). In addition to binary metal oxygen compounds, such as Zno, SnO₂ or In₂O₃, ternary metal oxygen compounds, such as Zn₂SnO₄, ZnSnO₃, MgIn₂O₄, GaInO₃, Zn₂In₂O₅ or In₄Sn₃O₁₂ or mixtures of different transparent conductive oxides also belong to the group of TCOs. Furthermore, the TCOs do not necessarily correspond to a stoichiometric composition and can also be p-doped or n-doped.

The contact layer serves to contact the epitaxial semiconductor layer sequence. Furthermore, the emitted electromagnetic radiation can be coupled out through this contact layer.

According to a further embodiment of the method, the carrier is configured for heat dissipation. For example, metallic carriers are suitable for heat dissipation.

According to a further embodiment of the method, the epitaxial semiconductor layer sequence is processed prior to mechanical detachment from the growth substrate. In particular, exposed surfaces of the epitaxial semiconductor layer sequence can be processed. For example, a mirror, a specular layer or a specular layer sequence is applied to a main surface of the epitaxial semiconductor layer sequence facing away from the growth substrate. Furthermore, an electrical contact layer and/or an electrical terminal, for example, is applied to the main surface of the epitaxial semiconductor layer sequence facing away from the growth substrate. Thereafter, the epitaxial semiconductor layer sequence is bonded, in particular permanently, to a carrier. Subsequently, the growth substrate is removed by mechanically detaching the epitaxial semiconductor layer sequence and the main surface facing away from the carrier is processed. In particular, the epitaxial semiconductor layer sequence is removed up to the etch stop layer and then electrically contacted.

### BRIEF DESCRIPTION OF THE DRAWINGS

Further advantageous embodiments and further developments of the method for producing a plurality of surface-emitting semiconductor laser diodes become apparent from the exemplary embodiments described below in connection with the figures.

FIGS. 1 to 8 schematically show various steps of a method for producing a plurality of surface-emitting semiconductor laser diodes according to an exemplary embodiment.

FIG. 9 shows a schematic sectional view of an epitaxially grown semiconductor layer stack according to an exemplary embodiment.

FIG. 10 shows a schematic sectional view of a surface-emitting semiconductor laser diode according to an exemplary embodiment.

FIG. 11 shows a schematic sectional view of an epitaxially grown semiconductor layer stack according to a further exemplary embodiment.

FIG. 12 shows a schematic sectional view of a surface-emitting semiconductor laser diode according to a further exemplary embodiment.

### DETAILED DESCRIPTION

Elements that are identical, similar or have the same effect have the same reference signs in the figures. The figures and the proportions of the elements shown in the figures are not to be regarded as true to scale. Rather, individual elements, in particular layer thicknesses, may be shown exaggeratedly large for better representability and/or understanding.

In the method according to the exemplary embodiment of FIGS. 1 to 8, a growth substrate 1 is first provided. The growth substrate is preferably a wafer, in particular with a diameter of at least 6 inches, and comprises sapphire, silicon carbide or gallium nitride, for example. Preferably, the growth substrate 1 comprises gallium nitride.

In a next step, a mask layer 2 having a plurality of openings 21 is applied to a main surface of the growth substrate 1, such that regions of the growth substrate are exposed through the openings, as shown in FIG. 1. The mask layer 2 is in direct contact with the growth substrate 1.

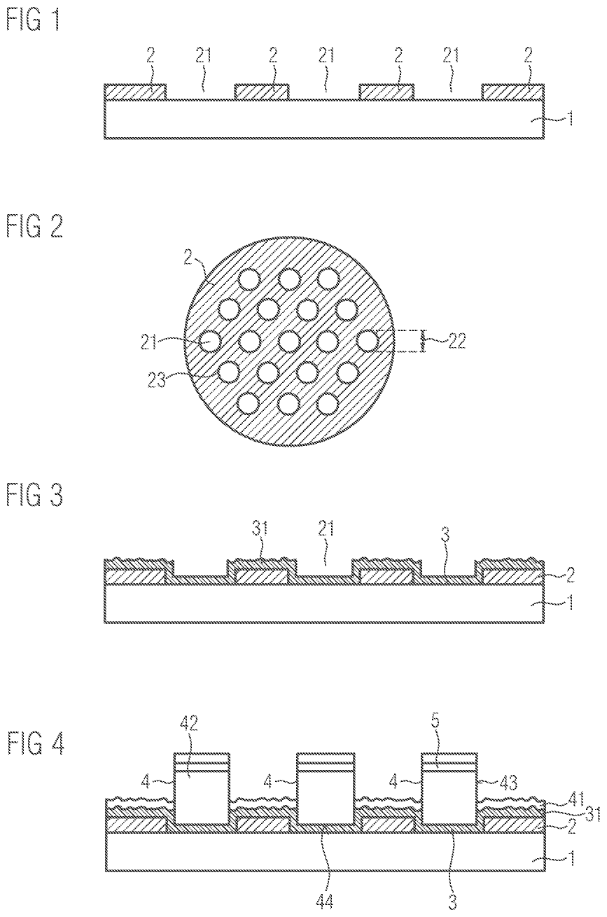

FIG. 2 shows a schematic top view of a wafer with a mask layer 2 having a plurality of circular openings 21 with a diameter 22.

The area of the openings 21 corresponds to the area of apertures 10 of the surface-emitting semiconductor laser diodes. The area of the openings 21 may also be larger than the area of apertures 10 of the surface-emitting semiconductor laser diodes. In this case, the diameter 22 of the openings 21 may be smaller than a distance between edges 23 of two directly adjacent openings 21. For example, the openings 21 have diameters 22 between 10 micrometers and 40 micrometers, inclusive, while the distance between edges 23 of two directly adjacent apertures is between 50 micrometers and 100 micrometers, inclusive, for example.

In order to increase the number of surface-emitting semiconductor laser diodes on a wafer, the distance between the edges 23 of two directly adjacent openings 21 may also be smaller than the diameter 22 of the openings 21. For example, the openings 21 have diameters 22 between 10 micrometers and 50 micrometers inclusive, while the distance between the edges 23 of two directly adjacent openings is approximately 10 micrometers, for example. In the case of a pick-and-place transfer of the semiconductor layer stacks to a carrier, the distances between the semiconductor layer stacks on the carrier can be selected to be correspondingly larger for a further chip process. In particular, this can increase the yield in the growth process and thus reduce costs.

FIG. 3 schematically shows a next method step in which a first intermediate layer 3 is deposited on the exposed regions of the growth substrate 1 and on the mask layer 2. In this process, a homogeneous first intermediate layer 3 forms only on the exposed regions of the growth substrate 1 within the openings 21. By contrast, inhomogeneous regions of the first intermediate layer 31, which have an inhomogeneous structure, form on the mask layer 2.

FIG. 4 schematically shows a next method step in which an epitaxial semiconductor layer sequence 42 is epitaxially grown on the intermediate layer 3. Due to the structure of the intermediate layer 3, epitaxial growth occurs only on the homogeneous regions of the first intermediate layer 3, which is arranged in particular on the exposed regions of the growth substrate 1. By contrast, the inhomogeneous structure in the inhomogeneous regions of the first intermediate layer 31 on the mask layer 2 results in the growth of an amorphous semiconductor material 41. Thus, epitaxial growth of the epitaxial semiconductor layer sequence 42 happens only in the regions of the openings 21 of the mask layer 2. Thereby, semiconductor layer stacks 4 form in the regions of the openings 21 of the mask layer 2. The combination of the mask layer 2 and the structure of the first intermediate layer 3 thus leads to an area-selective epitaxial growth of the epitaxial semiconductor layer sequence 42. The epitaxial semiconductor layer sequence 42 comprises an active layer 5 which is configured to generate electromagnetic radiation during operation. In this case, the growth conditions are set such that the semiconductor layer stacks 4 have vertical side surfaces 43. This is possible, for example, by suitably selecting the growth temperatures and/or the growth rates.

FIG. 5 schematically shows a further method step, wherein the epitaxial semiconductor layer sequence 42 comprises a second intermediate layer 6, which is arranged between the first intermediate layer 3 and the active layer 5 of the epitaxial semiconductor layer sequence 42. Disturbances at the edges 23 of the openings 21 of the mask layer 2, for example crystallization nuclei, can impair the epitaxial growth of the epitaxial semiconductor layer sequence 42. This may lead to crystal defects within the epitaxial semiconductor layer sequence 42. For this reason, the epitaxial semiconductor layer sequence 42 can generally only be grown slowly if a high crystal quality is required.

A second intermediate layer 6 within the epitaxial semiconductor layer sequence 42, which is located at a higher position than the highest point of the mask layer 2 in the growth direction of the epitaxial semiconductor layer sequence 42, can prevent the propagation of crystal defects into the area of the active layer 5. Furthermore, the epitaxial semiconductor layer sequence 42 on the second intermediate layer 6 can be grown more easily with higher crystal quality because due to less sharp edges there is less interference present, such as impurities caused by crystallization nuclei. The epitaxial semiconductor layer sequence 42 between the first intermediate layer 3 and the second intermediate layer 6 can be grown with lower crystal quality than the crystal quality of the active layer 5 without strongly affecting the crystal quality of the active layer 5. Thus, the overall epitaxial growth process can be accelerated.

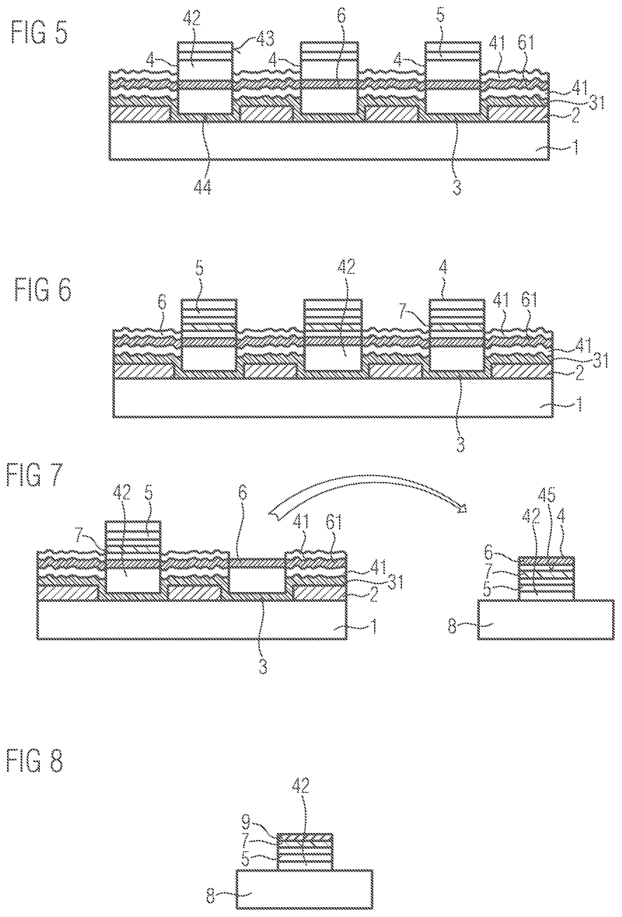

FIG. 6 schematically shows a further method step in which the epitaxial semiconductor layer sequence 42 comprises an additional etch stop layer 7 in comparison with FIG. 5. The etch stop layer is arranged between the active layer 5 and the intermediate layer 6 which is closest to the active layer. The etch stop layer 7 comprises aluminum nitride or silicon nitride, for example. In particular, the etch stop layer 7 allows a precise stopping of an etching process of the epitaxial semiconductor layer sequence 42. By removing the epitaxial semiconductor layer sequence 42 up to the etch stop layer 7 in a later process step, the thickness of semiconductor layer stacks 4 is precisely adjusted.

FIG. 7 schematically shows a further method step in which a semiconductor layer stack 4 is mechanically detached from the growth substrate 1 by means of a pick-and-place process and transferred to a carrier 8. Due to the weak van der Waals bonds within the first intermediate layer 3 and within the second intermediate layer 6, the semiconductor layer stack 4 generally mechanically detaches at or within one of the intermediate layers 3, 6. The intermediate layer at which the mechanical detachment occurs may be random. Since the semiconductor layer stack 4 is removed to the etch stop layer 7 in a further process step, it is immaterial whether the mechanical detachment occurs at the first intermediate layer 3 or at the second intermediate layer 6. Amorphous semiconductor material 41, which may still be present at the edge of the semiconductor layer stack 4 after transfer to the carrier 8, is removed in a further process step. An etching step for faceting and/or processing the side surfaces 43 of the semiconductor layer stack 4 is suitable for this purpose, for example.

The carrier 8 may be configured for heat dissipation and comprise, for example, a metallic substrate. Furthermore, the carrier 8 comprises an electrical contact layer for contacting the semiconductor layer sequence 42. Furthermore, the carrier 8 comprises a mirror, a reflective layer or a reflective layer sequence, for example a dielectric Bragg reflector 11. These are configured to form part of an optical cavity in which the epitaxial semiconductor layer sequence 42 is arranged.

FIG. 8 schematically shows a further method step in which the epitaxial semiconductor layer sequence 42 is removed up to the etch stop layer 7 after transfer to the carrier 8. Furthermore, an electrical contact layer 9 is applied. The removal up to the etch stop layer 7 is carried out, for example, by a wet or dry chemical etching process or by a mechanical grinding or polishing process. Since the electromagnetic radiation is coupled out during operation via the main surface 45 of the semiconductor layer stack 4 facing away from the carrier 8, the contact layer 9 comprises a transparent, electrically conductive material, for example indium tin oxide.

FIG. 9 shows a schematic sectional view of a semiconductor laser diode with an epitaxial semiconductor layer sequence 42 according to an embodiment. The epitaxial semiconductor layer sequence 42 has an active layer 5 and an etch stop layer 7 and is epitaxially grown on a substrate 1 with a mask layer 2 and a first intermediate layer 3. Thereby, amorphous semiconductor material 41 is formed on the inhomogeneous region of the first intermediate layer 31 over the carrier, as well as on the edge 23 of the openings 21 in the mask layer 2. In this exemplary embodiment, the area of the opening is larger than the area of the aperture of the surface-emitting semiconductor laser diode. For example, the diameter of the openings 21 is approximately 40 micrometers.

FIG. 10 shows a schematic sectional view of a surface-emitting semiconductor laser diode according to an exemplary embodiment, comprising a semiconductor layer stack 4 with an active layer 5. The side surfaces 43 of the semiconductor layer stack 4 do not have to be formed vertically. The semiconductor layer stack 4 is disposed between two dielectric Bragg reflectors 11 forming an optical cavity. The dielectric Bragg reflector 11, which is arranged on the main surface 45 of the semiconductor layer stack 4 facing away from the carrier 8, is curved. On the one hand, this reduces potential problems caused by slightly tilted dielectric Bragg reflectors 11. On the other hand, this affects the mode profile of the electromagnetic radiation 13 emitted during operation. In this exemplary embodiment, the electromagnetic radiation 13 is coupled out via the main surface 45 of the semiconductor layer stack 4 facing away from the carrier 8. A contact layer 9 of a TCO material and an electrically insulating layer 91, for example made of silicon oxide, are arranged on the semiconductor layer stack 4. The electrically insulating layer 91 is preferably ring-shaped and in particular defines the area of the aperture 10 of the semiconductor laser diode. The contact layer 9 is electrically contacted via an electrical terminal 92 which preferably completely surrounds the aperture 10 of the semiconductor laser diode. In this exemplary embodiment, the semiconductor layer stack 4 has a larger lateral extent than that of the aperture 10. For example, the lateral extent of the semiconductor layer stack 4 is 40 micrometers, while the aperture 10 has a diameter of 10 micrometers. In this case, the semiconductor material in a region laterally outside the aperture 10 remains inactive during operation of the semiconductor laser diode and does not contribute to the generation of electromagnetic radiation. This semiconductor material is configured to dissipate heat. The carrier 8 comprises copper, silicon or gallium nitride, for example, and a hybrid layer 81. The hybrid layer 81 comprises a metal, for example silver, and a dielectric Bragg reflector 11.

FIG. 11 shows a schematic sectional view of a surface-emitting semiconductor laser diode with an epitaxial semiconductor layer sequence 42 according to a further exemplary embodiment. Compared to FIG. 9, the growth conditions are adjusted, for example by suitably selecting the growth temperature and/or the growth rates, such that vertical side surfaces 43 are formed above the etch stop layer 7. In this exemplary embodiment, the area of the opening 21 corresponds to the area of the aperture 10 of the surface-emitting semiconductor laser diode. For example, the diameter of the openings 21 is approximately 10 micrometers. Below the etch stop layer 7, the side surface 43 has an arbitrary shape. This part of the epitaxial semiconductor layer sequence 42 is removed in a later process step by removing the semiconductor layer sequence up to the etch stop layer 7.

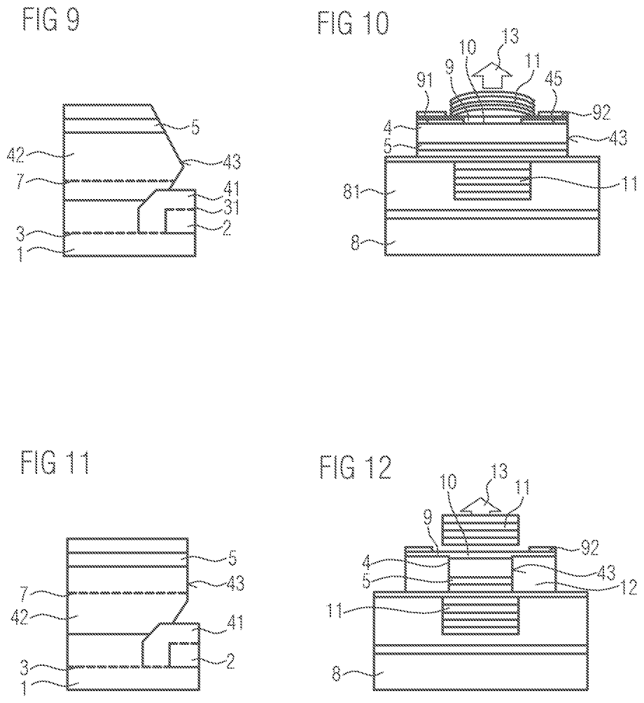

FIG. 12 shows a schematic sectional view of a surface-emitting semiconductor laser diode according to a further exemplary embodiment, comprising a semiconductor layer stack 4 with an active layer 5. The semiconductor layer stack 4 has vertical side surfaces 43. Further, the lateral extent of the semiconductor layer stack 4 corresponds to the diameter of the aperture 10. For example, the lateral extent of the semiconductor layer stack 4 is about 10 micrometers. The semiconductor layer stack 4 is arranged between two dielectric Bragg reflectors 11 that form an optical cavity. In this embodiment, the two dielectric Bragg reflectors 11 have flat main surfaces, but one or both of the dielectric

Bragg reflectors 11 can also be curved.

The electromagnetic radiation 13 emitted during operation is coupled out via the main surface 45 of the semiconductor layer stack 4 facing away from the carrier 8. In contrast to the exemplary embodiment in FIG. 10, the entire semiconductor material is active during operation of the semiconductor laser diode. In order to reduce light scattering at the side surfaces 43 of the semiconductor layer stack 4 during operation, the semiconductor layer stack 4 is faceted by an additional etching process or by appropriate conditions during the growth process that allow smooth and perpendicular side surfaces to produce particularly smooth side surfaces 43.

For heat dissipation, the semiconductor layer stack 4 is wrapped with a cladding 12 arranged on the side surfaces 43 of the semiconductor layer stack 4. The cladding 12 also serves as a waveguide for electromagnetic radiation 13 emitted during operation. The refractive index of the cladding 12 is smaller than the refractive index of the semiconductor material of the semiconductor layer stack 4, causing electromagnetic radiation within the semiconductor layer stack 4 to be reflected at the interface with the cladding 12. For example, the cladding 12 comprises aluminum nitride.

The invention is not limited to the exemplary embodiments by the description based on these exemplary embodiments. Rather, the invention encompasses any new feature as well as any combination of features, which in particular includes any combination of features in the patent claims, even if this feature or combination itself is not explicitly stated in the patent claims or the exemplary embodiments.

1. A method for producing a plurality of surface-emitting semiconductor laser diodes, comprising:
providing a growth substrate,
applying a mask layer having a plurality of openings onto the growth substrate, such that that regions of the growth substrate are exposed through the openings,
applying a first intermediate layer at least onto the exposed regions of the growth substrate, wherein the first intermediate layer comprises a quasi-two-dimensional material, and
epitaxially growing an epitaxial semiconductor layer sequence on the first intermediate layer, wherein the epitaxial semiconductor layer sequence comprises an active layer for generating electromagnetic radiation.

2. The method according to claim 1, wherein an area of the opening corresponds to an area of an aperture of the semiconductor laser diode.

3. The method according to claim 1, wherein at least one opening has an area larger than an aperture of the semiconductor laser diode.

4. The method according to claim 1, wherein the mask layer comprises a dielectric.

5. The method according to claim 1, wherein the quasi-two-dimensional material is selected from the group of: hexagonal boron nitride (h-BN), graphene, molybdenum disulfide, tungsten diselenide, fluorographene.

6. The method according to claim 1, wherein the first intermediate layer has a thickness between 0.5 nanometers and 100 nanometers, inclusive.

7. The method according to claim 1, wherein semiconductor layer stacks are epitaxially grown in the openings during epitaxial growth of the epitaxial semiconductor layer sequence.

8. The method according to claim 8, wherein the semiconductor layer stacks have vertical side surfaces.

9. The method according to claim 1, wherein the epitaxial semiconductor layer sequence comprises a nitride compound semiconductor material.

10. The method according to claim 1, wherein the epitaxial semiconductor layer sequence comprises at least a second intermediate layer which is arranged between a main surface of the epitaxial semiconductor layer sequence facing the first intermediate layer and the active layer, wherein the second intermediate layer comprises a quasi-two-dimensional material.

11. The method according to claim 1, wherein
the epitaxial semiconductor layer sequence comprises an etch stop layer, and
the etch stop layer is arranged between the active layer and the intermediate layer closest to the active layer.

12. The method according to claim 1, wherein the epitaxial semiconductor layer sequence is mechanically detached from at least one intermediate layer and transferred to a carrier.

13. The method according to claims 11, wherein the epitaxial semiconductor layer sequence is removed up to the etch stop layer.

14. The method according to claim 13, wherein a contact layer of a light-transmitting material is deposited on a main surface of the epitaxial semiconductor layer sequence facing away from the carrier.

15. The method according to claim 12, wherein the carrier is configured for heat dissipation.

16. The method according to claim 10, wherein between the first intermediate layer and the second intermediate layer a semiconductor layer is arranged that is free of a quasi-two-dimensional material.
